(19) United States
(12) Patent Application Publication
(10) Pub. No.: US 2026/0147052 A1
(43) Pub. Date: May 28, 2026

(54) REMOTE BATTERY DIAGNOSTIC APPARATUS AND METHOD AND STORAGE MEDIUM

(71) Applicant: SK On Co., Ltd., Seoul (KR)

(72) Inventors: Kyu Min HWANG, Daejeon (KR); Ung JON, Daejeon (KR)

(21) Appl. No.: 19/372,276

(22) Filed: Oct. 29, 2025

(30) Foreign Application Priority Data
Nov. 28, 2024 (KR) 10-2024-0173775
Mar. 14, 2025 (KR) 10-2025-0033269

(51) Int. Cl. G01R 31/371; B60L 58/16; G01R 31/367; G01R 31/3842; G01R 31/392; G01R 31/396; H01M 10/42; H01M 10/48

(52) U.S. Cl. CPC G01R 31/371; B60L 58/16; G01R 31/367; G01R 31/3842; G01R 31/392; G01R 31/396; H01M 10/425; H01M 10/482; H01M 10/486; H01M 2010/4271; H01M 2010/4278

(57) ABSTRACT

A remote battery diagnostic apparatus includes a remote controller remotely disposed from a device in which a battery including a plurality of battery cells is disposed and remotely receiving discrete time voltage data of each of the plurality of battery cells from a battery management controller of the battery, wherein the remote controller detects a battery cell outside a normal range of fluctuation index distribution data in which the plurality of battery cells are distributed according to a voltage fluctuation index of the discrete time voltage data and generates diagnostic information for the battery.

### CROSS-REFERENCE TO RELATED APPLICATION(S)

This patent document claims the priority and benefits of Korean Patent Application Nos. 10-2024-0173775 filed on Nov. 28, 2024 and 10-2025-0033269 filed on Mar. 14, 2025, the disclosures of which are incorporated herein by reference in their entirety.

### TECHNICAL FIELD

The disclosure and implementations disclosed in this patent document generally relate to a remote battery diagnostic apparatus, method, and storage medium.

### BACKGROUND

Batteries have been widely used not only in small electronic devices, such as mobile phones and laptops, but also in medium-to large-sized mechanical devices, such as electric vehicles. Batteries may be implemented as secondary batteries and thus have the advantage of being rechargeable and reusable.

Since the safety of batteries affect the safety of electronic and mechanical devices including batteries, and thus, it is important to secure the safety of batteries. Sensing information (e.g., current, voltage, temperature) on the batteries may be used to ensure battery safety, and a battery management system (BMS) may manage batteries based on the sensing information.

### SUMMARY

In the self-diagnosis of a battery by a battery management system (BMS), it may be difficult to meet the overall data throughput required for diagnosis, and there may be a limitation in increasing the performance (e.g., accuracy, reliability, and speed) of the self-diagnosis of the battery by the BMS.

The present disclosure may be implemented in some embodiments to provide a remote battery diagnostic apparatus, method and storage medium, capable of advantageously satisfying the overall data throughput required for diagnosis and improving battery diagnostic performance (e.g., accuracy, reliability, and speed).

In some embodiments of the present disclosure, a remote battery diagnostic apparatus includes: a remote controller remotely disposed from a device in which a battery including a plurality of battery cells is disposed and remotely receiving discrete time voltage data of each of the plurality of battery cells from a battery management controller of the battery, wherein the remote controller detects a battery cell outside a normal range of fluctuation index distribution data in which the plurality of battery cells are distributed according to a voltage fluctuation index of the discrete time voltage data and generates diagnostic information for the battery.

The remote controller may generate discrete time voltage variation data of the discrete time voltage data and generate standard deviation data of the discrete time voltage variation data as the voltage fluctuation index.

An adjacent time interval of the discrete time voltage data may be 1 minute or less, and the discrete time voltage variation data may correspond to a differential value of the discrete time voltage data.

The remote controller may generate, as the fluctuation index distribution data, distribution of standard deviation data in which standard deviation data of each of the plurality of battery cells is distributed, and determine, as the normal range, a Gaussian distribution range of the standard deviation data of each of the plurality of battery cells.

The remote controller remotely may receive discrete time current data of the battery from the battery management controller, select valid discrete time voltage data among the discrete time voltage data based on the discrete time current data, detect a battery cell outside the normal range of the fluctuation index distribution data in which the plurality of battery cells are distributed according to the voltage fluctuation index of the valid discrete time voltage data, and generate diagnostic information for the battery.

The remote controller may select, as the valid discrete time voltage data, the discrete time voltage data, in which the discrete time current data or discrete time current variation data of the discrete time current data falls within a reference range.

The remote controller may remotely receive at least one of discrete time current data or discrete time temperature data of the battery from the battery management controller, determine an idle period of the battery based on at least one of the discrete time current data or the discrete time temperature data, detect a battery cell outside a normal range in the fluctuation index distribution data in which the plurality of battery cells are distributed according to the voltage fluctuation index of the discrete time voltage data corresponding to the idle period, and generate diagnostic information for the battery.

The remote controller may detect a battery cell discontinuously distributed among the plurality of battery cells distributed in the fluctuation index distribution data, as the battery cell outside the normal range.

The remote controller may determine a battery cell with a voltage change greater than an upper limit of the normal range in the fluctuation index distribution data to be an internal short-circuit battery cell and generate diagnostic information for the battery.

The remote controller may remotely transmit diagnostic information for the battery to the battery management controller.

The remote controller may remotely receive discrete time voltage data of a plurality of battery cells, each including a plurality of battery cells, from a plurality of battery management controllers respectively corresponding to the plurality of batteries and generate diagnostic information for each of the plurality of batteries.

The device in which the battery is disposed may include a vehicle, the battery and the battery management controller may be disposed in the vehicle, and the remote controller may be disposed remotely from the vehicle.

In some embodiments of the present disclosure, a remote battery diagnostic method includes: a remote controller remotely disposed from a device in which a battery including a plurality of battery cells is disposed and remotely receiving discrete time voltage data of each of the plurality of battery cells from a battery management controller of the battery, and generating diagnostic information for the battery by detecting a battery cell outside a normal range of fluctuation index distribution data in which the plurality of battery cells are distributed according to a voltage fluctuation index of the discrete time voltage data.

The generating of the diagnostic information may include: extracting discrete time voltage variation data of the discrete time voltage data; and extracting, as the voltage fluctuation index, standard deviation data of the discrete time voltage variation data.

The generating of the diagnostic information may further include: generating, as the fluctuation index distribution data, distribution of standard deviation data in which standard deviation data of each of the plurality of battery cells is distributed; and generating diagnostic information for the battery by determining a battery cell having a voltage change greater than an upper limit of the normal range in the fluctuation index distribution data to be an internal short-circuit battery cell.

The generating of the diagnostic information may further include remotely transmitting the diagnostic information for the battery to the battery management controller.

The generating of the diagnostic information may include checking whether a replacement cycle of the distribution of standard deviation data has expired, using previously generated distribution of standard deviation data to determine a next internal short-circuit when the replacement cycle has not expired, and updating the distribution of standard deviation data when the replacement cycle has expired.

The remotely receiving may include remotely receiving at least one of discrete time current data or discrete time temperature data of the battery from the battery management controller, and the generating of the diagnostic information may include selecting discrete time voltage data belonging to a time range determined based on at least one of the discrete time current data or the discrete time temperature data and generating diagnostic information for the battery by detecting a battery cell outside the normal range of the fluctuation index distribution data in which the plurality of battery cells are distributed according to a voltage fluctuation index of the selected discrete time voltage data.

The remotely receiving may include remotely receiving discrete time voltage data of the plurality of battery cells from a plurality of battery management controllers respectively corresponding to a plurality of batteries, each including a plurality of battery cells, the device in which the battery is disposed may include a vehicle, the vehicle may be a plurality of vehicles, the plurality of batteries and the plurality of battery management controllers may be disposed in the plurality of vehicles, and the generating of the diagnostic information may include generating diagnostic information for each of the plurality of batteries.

In some embodiments of the present disclosure, there is provided a storage medium recorded thereon one or more programs including instructions for executing the remote battery diagnosis method.

### BRIEF DESCRIPTION OF DRAWINGS

Certain aspects, features, and advantages of the present disclosure are illustrated by the following detailed description with reference to the accompanying drawings.

FIG. 1 is a diagram illustrating a battery and a battery management controller, which are diagnostic targets of a remote battery diagnostic apparatus, method, and storage medium, according to an embodiment of the present disclosure, disposed in a vehicle;

FIG. 2 is a diagram illustrating a remote battery diagnostic apparatus, method, and storage medium diagnosing a plurality of batteries according to an embodiment of the present disclosure;

FIG. 3 is a diagram illustrating a battery and a battery management controller, which are diagnostic targets of a remote battery diagnostic apparatus, method, and storage medium, according to an embodiment of the present disclosure;

FIG. 4 is a diagram illustrating a remote battery diagnostic apparatus, method, and storage medium according to an embodiment of the present disclosure;

FIG. 5 is a graph illustrating discrete time voltage data of a remote battery diagnostic apparatus, method, and storage medium according to an embodiment of the present disclosure;

FIG. 6 is a graph illustrating discrete time voltage variation data of a remote battery diagnostic apparatus, method, and a storage medium according to an embodiment of the present disclosure;

FIG. 7 is a graph illustrating voltage variation indices (e.g., voltage variation standard deviation) over battery cell of a remote battery diagnostic apparatus, method, and storage medium according to an embodiment of the present disclosure;

FIG. 8 is a graph illustrating fluctuation index distribution data (e.g., distribution of standard deviation data) for a remote battery diagnostic apparatus, method, and storage medium according to an embodiment of the present disclosure;

FIG. 9 is a graph illustrating the detection of battery cells outside a normal range of fluctuation index distribution data for a remote battery diagnostic apparatus, method, and storage medium according to an embodiment of the present disclosure;

FIG. 10 is a graph illustrating voltage variation differences depending on the presence or absence of internal short-circuits in a plurality of battery cells which are diagnostic targets of a remote battery diagnostic apparatus, method, and storage medium according to an embodiment of the present disclosure;

FIG. 11 is a flowchart illustrating a remote battery diagnostic apparatus, method, and storage medium according to an embodiment of the present disclosure;

FIG. 12 is a flowchart specifically illustrating an operation of generating diagnostic information in a remote battery diagnostic apparatus, method, and storage medium, according to an embodiment of the present disclosure;

FIG. 13 is a flowchart illustrating a remote battery diagnostic apparatus, method, and storage medium, remotely receiving discrete time current data (and/or temperature data) of a battery and selecting valid discrete time voltage data, according to an embodiment of the present disclosure; and

FIG. 14 is a flowchart illustrating a remote battery diagnostic apparatus, method, and storage medium, accumulatively using fluctuation index distribution data (e.g., distribution of standard deviation data) over replacement cycle, according to an embodiment of the present disclosure.

### DETAILED DESCRIPTION

Specific details of other embodiments are included in the detailed description and drawings.

The advantages and features of the present disclosure, and methods for achieving them, will become clearer with reference to the embodiments described in detail below with the accompanying drawings. However, the present disclosure is not limited to the embodiments disclosed below and may be implemented in various different forms. These embodiments are provided solely to ensure that the disclosure of the present disclosure is complete and to fully inform those skilled in the art of the scope of the disclosure, and the present disclosure is defined solely by the scope of the claims. Like reference numerals may refer to like elements throughout the specification.

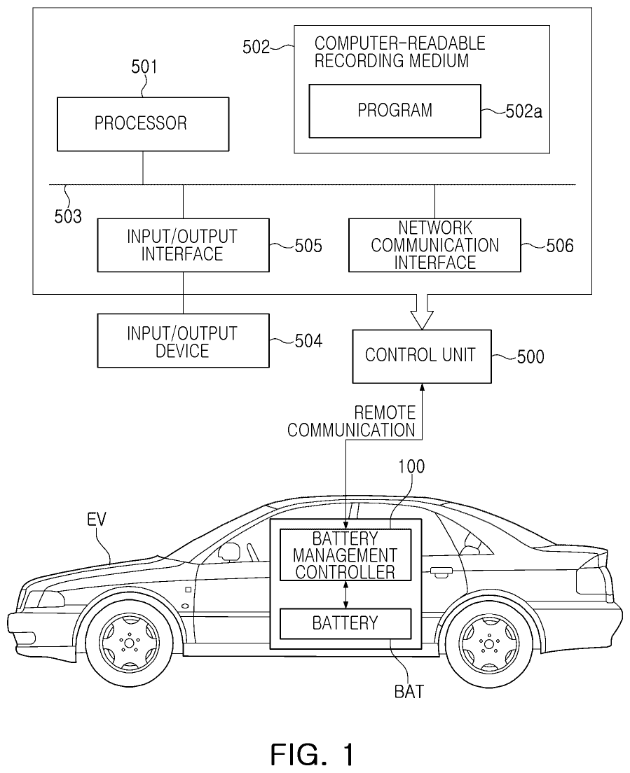

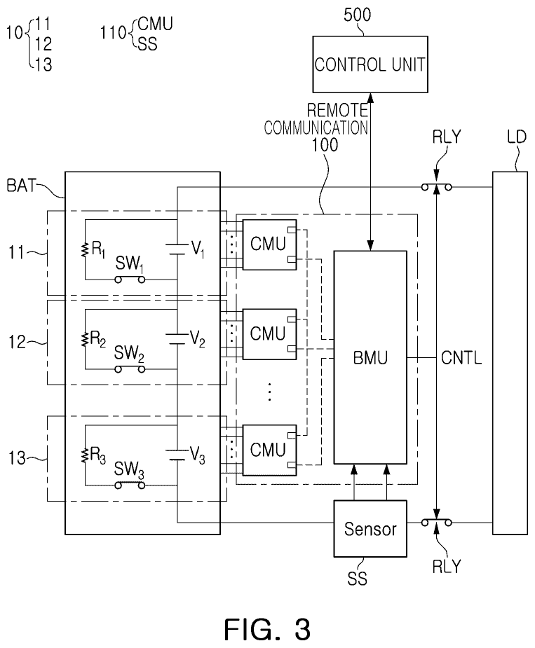

Referring to FIGS. 1 and 3, a battery BAT may include a plurality of battery cells 10. For example, the battery BAT may be implemented as a battery pack or a battery module. The battery pack may include a plurality of battery modules, each including a plurality of battery cells. For example, each of the plurality of battery cells 10 may include a case accommodating an electrode assembly and an electrolyte and a lead tab electrically connected to the electrode assembly and protruding from at least one side of the case. The electrode assembly may be configured such that positive and negative electrode plates are laminated with wide surfaces thereof facing each other, with a separator interposed therebetween. The separator may be configured to prevent electrical shorting between the positive and negative electrode plates and to facilitate ion flow. For example, the separator may include a porous polymer film or a porous non-woven fabric. For example, each of the plurality of battery cells 10 may be implemented to have one of pouch-type, cylindrical, or prismatic shapes, but is not limited thereto.

A battery management controller 100 may control the management of the battery BAT and may be disposed in a device (e.g., a vehicle EV) in which the battery BAT is disposed. For example, the battery management controller 100 may include a battery management unit BMU and/or a plurality of cell monitoring units CMU. A voltage measurement unit 110 may include a plurality of cell monitoring units CMU and/or battery current sensors SS.

For example, the battery management unit BMU of the battery management controller 100 may control a relay RLY to determine whether to establish an electrical connection between the battery BAT and a load LD (e.g., a motor, an inverter, etc.) based on whether a current value sensed by the battery current sensor SS exceeds an overcurrent reference value. For example, the battery management unit BMU of the battery management controller 100 may control the relay RLY to determine whether to establish an electrical connection between the battery BAT and a load LD based on whether a voltage value and/or temperature value sensed by the plurality of cell monitoring units CMU exceed a reference. Accordingly, further deterioration of the battery BAT condition may be prevented, and the safety of the battery BAT and the vehicle EV equipped with the battery BAT may be improved. This may be an example of battery management (diagnosis) control.

For example, the battery management unit BMU of the battery management controller 100 may be used to generate at least one of state of charge (SOC) information and state of health (SOH) information of the battery BAT based on at least one of the voltage, current, and temperature values sensed by the voltage measurement unit 110 and improve management efficiency (e.g., to improve relay RLY control accuracy) for the battery BAT based on the SOC information and/or the SOH information. This may be an example of battery management (diagnosis) control.

Depending on the design, the relay RLY control of the battery management unit BMU may be redisposed by control of a plurality of battery cells 11, 12, and 13 and a plurality of switches SW1, SW2, and SW3 connected to a plurality of resistors R1, R2, and R3, or additional control for the plurality of switches SW1, SW2, and SW3 may be added as an auxiliary measure.

Since the space in a device (e.g., an electric vehicle EV) in which the battery BAT is disposed may be limited, the size of the battery management controller 100 disposed in the device (e.g., an EV) may also be limited. For example, the battery management controller 100 may be implemented as a semiconductor integrated circuit (IC) or chipset.

The overall data throughput of a battery management controller 100 may be proportional to the size of the battery management controller 100. Therefore, the overall data throughput of the battery management controller 100 with limited size may also be limited. As the diagnostic principle is more accurate, the overall data throughput required to implement the diagnostic principle may become greater. Therefore, the battery management controller 100 with limited overall data throughput may have limitations in improving the performance (e.g., accuracy, reliability, and speed) of its own battery BAT diagnostics.

The remote battery diagnostic apparatus according to an embodiment of the present disclosure may include a remote controller 500 remotely located from the device (e.g., a vehicle EV) in which the battery BAT including a plurality of battery cells 10 is located. For example, the remote controller 500 may be located remotely from the vehicle EV.

Since the remote controller 500 is not affected by the space constraints of the device (e.g., vehicle EV) in which the battery BAT is disposed, the remote controller 500 may advantageously be implemented on a larger scale, as compared to the battery management controller 100. Therefore, the overall data throughput of the remote controller 500 may be greater than that of the battery management controller 100, and the overall data throughput required to implement the diagnostic principle may be more easily met and the diagnostic performance (e.g., accuracy, reliability, and speed) of the battery BAT may be further improved.

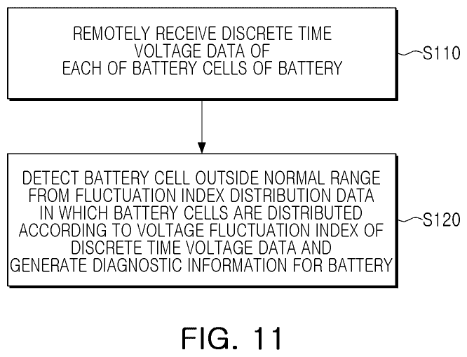

Referring to FIGS. 1, 10, and 11, in a remotely receiving operation (S110), the remote controller 500 may remotely receive discrete time voltage data (V1, V2, and V3 of FIG. 10) of each of the plurality of battery cells 10 from the battery management controller 100. For example, a plurality of cell monitoring units CMU of the battery management controller 100 may respectively generate voltage data and/or temperature data of the plurality of battery cells 11, 12, and 13 by monitoring the plurality of battery cells 11, 12, and 13, and transmit the voltage data and/or temperature data to the battery management unit BMU (e.g., transmit via a serial peripheral interface (SPI), a universal asynchronous receiver/transmitter (UART), or an inter integrated circuit (I2C)). The battery current sensor SS may generate current data of the plurality of battery cells 11, 12, and 13, and transmit the current data to the battery management unit BMU. The battery management unit BMU may remotely transmit at least one of the voltage data, current data, and temperature data to the remote controller 500 by remotely communicating with the remote controller 500.

In operation S120 of generating diagnostic information, the remote controller 500 may detect a battery cell outside a normal range in a fluctuation index distribution data in which the plurality of battery cells (10 in FIG. 3) are distributed according to a voltage fluctuation index of the discrete time voltage data (V1, V2, and V3 in FIG. 10) and generate diagnostic information (e.g., information on the presence or absence of an internal short-circuit) for the battery BAT.

A self-discharge rate (SDR) of the respective voltages V1, V2, and V3 of the plurality of battery cells 11, 12, and 13 may increase as the magnitude of the internal short-circuit in each of the plurality of battery cells 11, 12, and 13 increases. As the self-discharge rate (SDR) is higher, the fluctuation in the respective voltages V1, V2, and V3 of the plurality of battery cells 11, 12, and 13 may be greater. For example, the fluctuations in the discrete time voltage data (V_abnormal in FIG. 10) of a battery cell with an internal short-circuit may be greater than the fluctuations in the discrete time voltage data (V_normal in FIG. 10) of a battery cell without an internal short-circuit.

While a diagnosis principle based on the voltage fluctuation index may be advantageous in increasing diagnostic accuracy and reliability, it may require a significant amount of overall data throughput to implement the diagnostic principle. As the number of battery cells 11, 12, and 13 increases, the overall data throughput required to generate the voltage fluctuation index data for each of the battery cells 11, 12, and 13 may also increase.

The remote controller 500 is not affected by the space constraints of the device (e.g., vehicle EV) in which the battery BAT is disposed, and thus, the remote controller 500 may be advantageously implemented on a larger scale than the battery management controller 100, may satisfy the overall data throughput required to implement the diagnostic principle based on the voltage fluctuation index, and improve the diagnostic performance (e.g., accuracy, reliability, and speed) of the battery BAT.

Also, the voltage fluctuation index may be affected by variables (e.g., SOC, SOH, current, and temperature) other than the self-discharge rate, but the conditions (e.g., SOC, SOH, current, and temperature) of the plurality of battery cells 11, 12, and 13 distributed in the fluctuation index distribution data may be substantially identical. Accordingly, the remote controller 500 may eliminate the influence of variables (e.g., SOC, SOH, current, temperature) other than the self-discharge rate in the process of generating the fluctuation index distribution data, and thus, the presence or absence of an internal short-circuit in each of the plurality of battery cells 11, 12, and 13 may be more accurately detected and the diagnostic performance (e.g., accuracy, reliability, speed) for the battery BAT may be further improved.

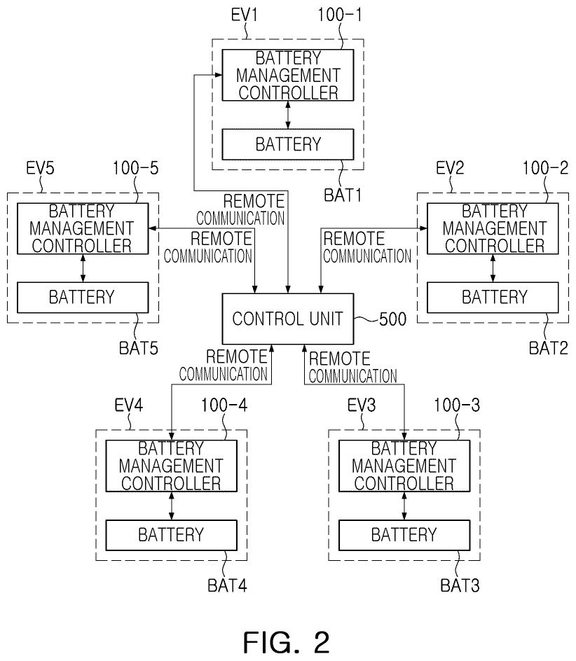

Referring to FIG. 2, the remote controller 500 may remotely receive discrete time voltage data of a plurality of battery cells from a plurality of battery management controllers 100-1, 100-2, 100-3, 100-4, and 100-5 respectively corresponding to a plurality of batteries BAT1, BAT2, BAT3, BAT4, and BAT5, each including a plurality of battery cells (10 in FIG. 3) and may generate diagnostic information (e.g., information on the presence or absence of an internal short-circuit) for each of the plurality of batteries BAT1, BAT2, BAT3, BAT4, and BAT5. The plurality of batteries BAT1, BAT2, BAT3, BAT4, and BAT5 and the plurality of battery management controllers 100-1, 100-2, 100-3, 100-4, and 100-5 may be disposed in a plurality of vehicles EV1, EV2, EV3, EV4, and EV5.

Due to the principle of economies of scale, increasing the scale (overall data throughput) of the remote controller 500 may be more efficient than increasing the scale (overall data throughput) of each of the plurality of battery management controllers 100-1, 100-2, 100-3, 100-4, and 100-5. This is because the remote controller 500 is practically free from location constraints. Therefore, the remote controller 500, which is advantageous in increasing the scale (overall data throughput), may efficiently improve the overall diagnostic performance (e.g., accuracy, reliability, speed) for the plurality of batteries BAT1, BAT2, BAT3, BAT4, and BAT5.

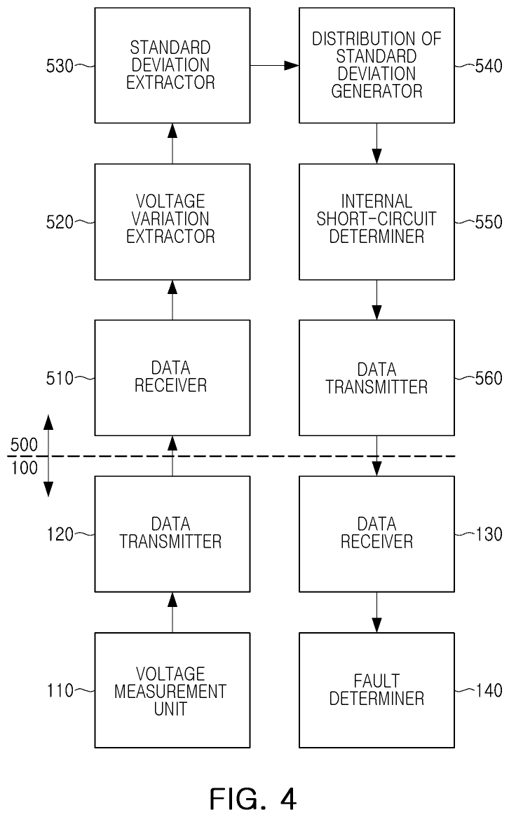

Referring to FIG. 4, the battery management controller 100 may include at least one of a voltage measurement unit 110, a data transmitter 120, a data receiver 130, and a fault determiner 140. The voltage measurement unit 110 may include a plurality of cell monitoring units (CMUs of FIG. 3) and/or battery current sensors (SSs of FIG. 3), and the battery management unit (BMU of FIG. 3) may include at least one of the data transmitter 120, the data receiver 130, and the fault determiner 140. For example, the data transmitter 120 and data receiver 130 may be implemented as structures (e.g., antennas, communication modules) for wireless communication within the battery management unit BMU (see FIG. 3), and the fault determiner 140 may be implemented as a relay RLY control logic within the battery management unit (see FIG. 3).

The remote controller 500 may include at least one of a data receiver 510, a voltage variation extractor 520, a standard deviation extractor 530, a distribution of standard deviation generator 540, an internal short-circuit determiner 550, and a data transmitter 560. For example, the data receiver 510 and data transmitter 560 may be implemented as a network communication interface (506 in FIG. 1), and the voltage variation extractor 520, the standard deviation extractor 530, the distribution of standard deviation generator 540, and the internal short-circuit determiner 550 may be implemented as a processor (501 in FIG. 1) and/or a computer-readable storage medium (502 in FIG. 1).

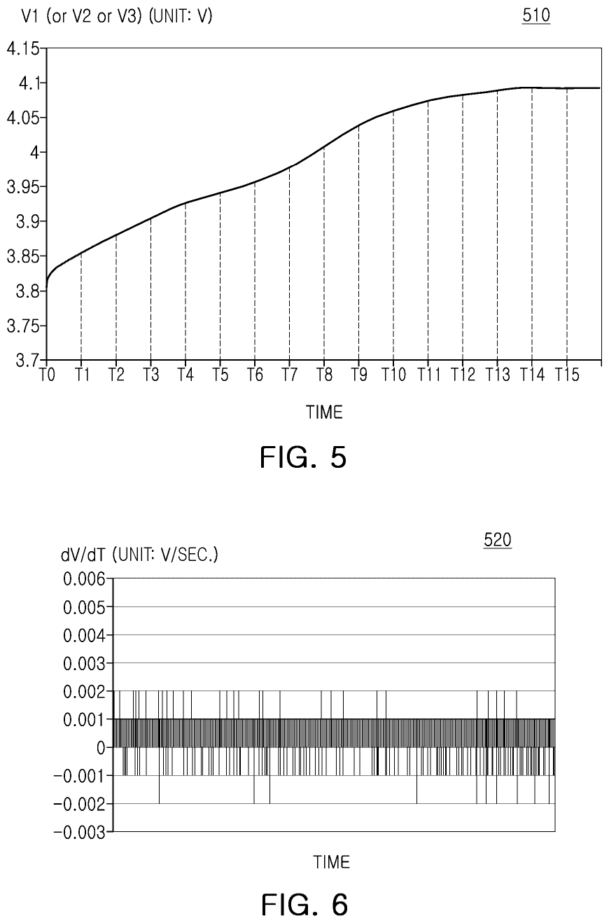

Referring to FIGS. 4, 5, and 12, in the remotely receiving operation (S110), the data receiver 510 of the remote controller 500 may remotely receive discrete time voltage data (V1, V2, and V3 in FIG. 5) for each of a plurality of battery cells from the data transmitter 120 of the battery management controller 100.

For example, an adjacent time interval of the discrete time voltage data (V1, V2, and V3 in FIG. 5) may be 1 minute or less (e.g., 30 seconds). Assuming that an n-th time (TIME) is Tn, the adjacent time interval may be the average of a time interval between Tn and T(n−1) and a time interval between Tn and T(n+1). Since the overall data throughput of the remote controller 500 may be required more as the adjacent time interval is shorter, the adjacent time interval may be appropriately set according to the scale of the remote controller 500. For example, the period at which the data receiver 510 of the remote controller 500 remotely receives may be an integer multiple of the adjacent time interval and may be appropriately set according to the performance (e.g., transmission power, frequency, bandwidth) of the structure (e.g., antenna, communication module) for wireless communication within the battery management controller 100.

Referring to FIGS. 4, 6, and 12, in operation S120 of generating diagnostic information, the voltage variation extractor 520 of the remote controller 500 may generate (extract (S122)) discrete time voltage variation data (dV/dT in FIG. 6) of the discrete time voltage data (V1, V2, and V3 in FIG. 5).

For example, the discrete time voltage variation data (dV/dT in FIG. 6) may correspond to a differential value of discrete time voltage data (V1, V2, and V3 in FIG. 5). The differential value may include a value obtained by dividing a first difference between the voltage at Tn and the voltage at T(n−1) by the adjacent time interval, may include a value obtained by dividing a second difference between the voltage at Tn and the voltage at T(n+1) by the adjacent time interval, and may include an average value (interpolation may be additionally applied) of the first and second difference values.

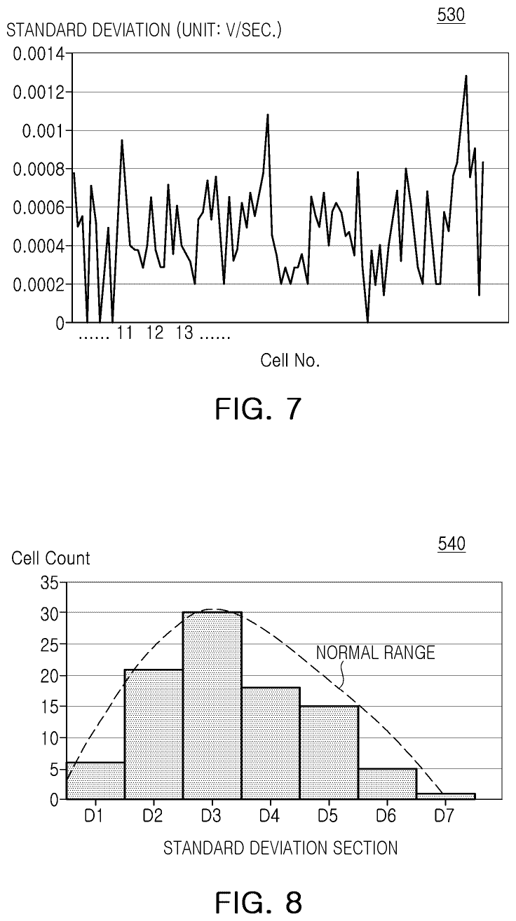

Referring to FIGS. 4, 7, and 12, in the operation (S120) of generating diagnostic information, the standard deviation extractor 530 of the remote controller 500 may generate (extract (S123)) standard deviation data (standard deviation in FIG. 7) of the discrete time voltage variation data (dV/dT in FIG. 6), as a voltage fluctuation index.

For example, the standard deviation extractor 530 of the remote controller 500 may add the squares of each of the discrete time voltage variation data (dV/dT of FIG. 6) of the battery cell 11, divide the sum by the number of discrete time voltage variation data (dV/dT of FIG. 6), and generate the square root of the sum as standard deviation data. Alternatively, the standard deviation extractor 530 of the remote controller 500 may add the absolute values of the discrete time voltage variation data (dV/dT of FIG. 6) of the battery cell 11, divide the sum by the number of discrete time voltage variation data (dV/dT of FIG. 6), and generate a corresponding value as standard deviation data. The remote controller 500 may add sequence (Cell No.) data of each of the plurality of battery cells 11, 12, and 13 to the standard deviation data of each of the plurality of battery cells 11, 12, and 13.

Referring to FIGS. 4, 8, and 12, in the operation (S120) of generating diagnostic information, the distribution of standard deviation generator 540 of the remote controller 500 may generate distribution of standard deviation data (Cell Count in FIG. 8) in which the standard deviation data (standard deviation in FIG. 7) of each of the plurality of battery cells 11, 12, and 13 is distributed as fluctuation index distribution data (S124) and determine a Gaussian distribution range of the standard deviation data of each of the plurality of battery cells 11, 12, and 13 as the normal range.

For example, the distribution of standard deviation generator 540 of the remote controller 500 may generate data of a plurality of standard deviation sections D1, D2, D3, D4, D5, D6, and D7 and sequentially increase (count) the values of the data of the plurality of standard deviation sections D1, D2, D3, D4, D5, D6, and D7 corresponding to the standard deviation data of each of the plurality of battery cells 11, 12, and 13 from 0 to 1 according to the order of the plurality of battery cells 11, 12, and 13. For example, the number of battery cells belonging to the standard deviation section D3 among the plurality of battery cells 11, 12, and 13 may be 30, which is the largest number.

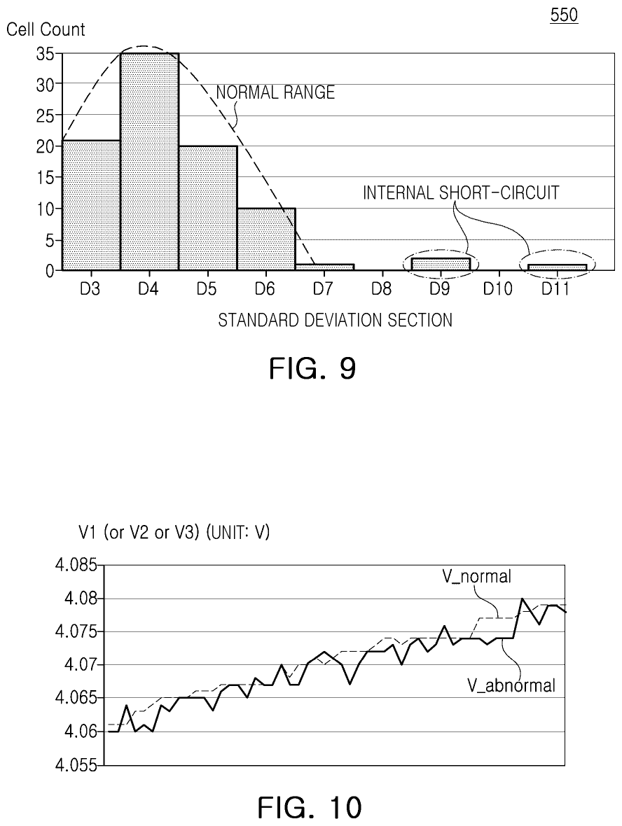

Referring to FIGS. 4, 9, and 12, in the operation (S120) of generating diagnostic information, the internal short-circuit determiner 550 of the remote controller 500 may detect, as a battery cell outside the normal range, at least one of a plurality of battery cells distributed in the fluctuation index distribution data (e.g., Cell Count of FIG. 9), which is discontinuously distributed (e.g., D7 and D9 are discontinuous) from the rest (battery cells belonging to D3, D4, D5, D6, and D7 of FIG. 9). A standard deviation range width of each of the plurality of standard deviation sections D1, D2, D3, D4, D5, D6, and D7 may be identical to each other.

Alternatively, the internal short-circuit determiner 550 of the remote controller 500 may determine (S125) that a battery cell with a voltage change (e.g., D8, D9, D10, and D11 in FIG. 9) greater than an upper limit (e.g., D7 in FIG. 9) of the normal range in the fluctuation index distribution data (e.g., Cell Count in FIG. 9) is an internal short-circuit battery cell and generate diagnostic information on the battery. The upper limit (e.g., D7 in FIG. 9) may be set to a horizontal axis value at which a vertical axis value of the normal range (e.g., the Gaussian distribution range) begins to fall below a specific value (e.g., 1). Alternatively, the upper limit (e.g., D7 in FIG. 9) may be set to an upper distribution boundary (e.g., upper 0.13%) of the normal range (e.g., the Gaussian distribution range).

The normal range (e.g., the Gaussian distribution range) may depend on the overall voltage fluctuation index of the plurality of battery cells 11, 12, and 13, and the normal range (e.g., the Gaussian distribution range) and the overall voltage fluctuation index may be affected by variables (e.g., SOC, SOH, current, temperature) other than the self-discharge rate of the plurality of battery cells 11, 12, and 13. Therefore, the remote controller 500 may diagnose the plurality of battery cells 11, 12, and 13 based on the normal range (e.g., the Gaussian distribution range), thereby eliminating the influence of the variables (e.g., SOC, SOH, current, temperature) other than the self-discharge rate, more accurately detect the presence or absence of an internal short-circuit in each of the plurality of battery cells 11, 12, and 13, and further improve the diagnostic performance (e.g., accuracy, reliability, speed) of the battery BAT.

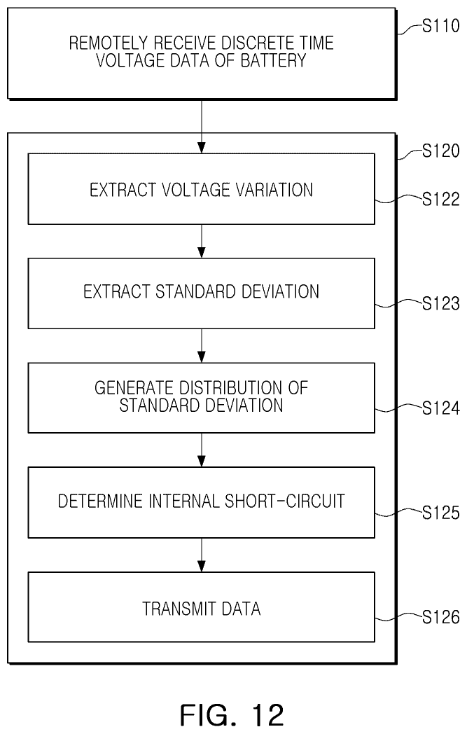

Referring to FIGS. 4 and 12, in operation S120 of generating diagnostic information, the data transmitter 550 of the remote controller 500 may remotely transmit diagnostic information regarding the battery BAT to the data receiver 130 of the battery management controller 100 (S126). For example, the diagnostic information regarding the battery BAT may include a battery replacement guide signal corresponding to information indicating an internal short-circuit, and the fault determiner 140 of the battery management controller 100 may output the battery replacement guide signal or transmit the battery replacement guide signal to a device (e.g., a vehicle) based on the battery replacement guide signal.

The plurality of cell monitoring units (CMUs in FIG. 3) of the voltage measurement unit 110 may generate voltage data and/or temperature data for each of the plurality of battery cells 11, 12, and 13, and the battery current sensor (SS in FIG. 3) of the voltage measurement unit 110 may generate current data for each of the plurality of battery cells 11, 12, and 13.

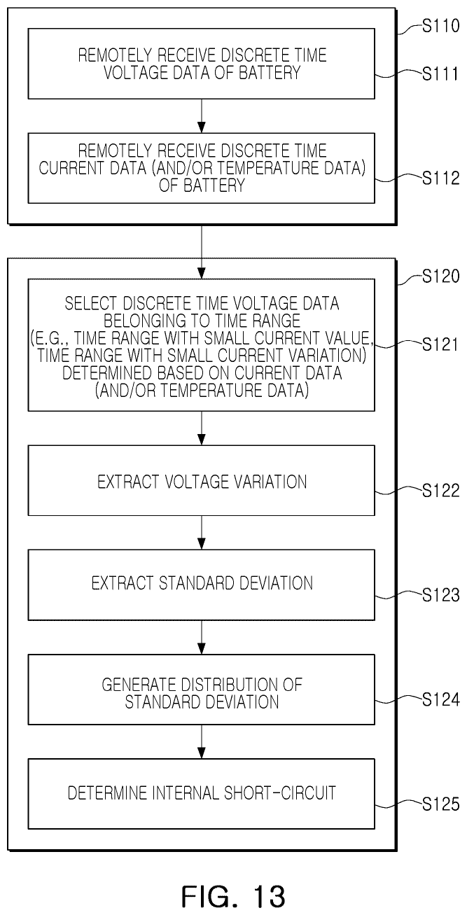

Referring to FIGS. 4 and 13, in the remotely receiving operation (S110), the data receiver 510 of the remote controller 500 may remotely receive (S111) the discrete time voltage data for each of the plurality of battery cells 11, 12, and 13 of the battery BAT from the data transmitter 120 of the battery management controller 100 and remotely receive (S112) the discrete time current data (and/or temperature data) of the battery BAT.

In operation S120 of generating diagnostic information, the voltage variation extractor 520 of the remote controller 500 may select valid discrete time voltage data from among the discrete time voltage data based on the discrete time current data (and/or temperature data) (S121). In operation S120 of generating diagnostic information, the remote controller 500 may detect battery cells outside the normal range in the voltage fluctuation index distribution data, in which the plurality of battery cells 11, 12, and 13 are distributed according to the voltage fluctuation index of the valid discrete time voltage data and generate diagnostic information for the battery BAT.

The extent to which the voltages of the plurality of battery cells 11, 12, and 13 are affected by variables (e.g., SOC, SOH, current, temperature) other than the self-discharge rate of the plurality of battery cells 11, 12, and 13 may vary depending on the condition of the battery BAT. For example, the remote controller 500 may select, as valid discrete time voltage data, discrete time voltage data of a period during which the influence of variables (e.g., SOC, SOH, current, temperature) other than the self-discharge rate is low based on the current data (and/or temperature data). Accordingly, the diagnostic performance (e.g., accuracy, reliability, and speed) of the battery BAT may be further improved.

For example, in operation S120 of generating diagnostic information, the remote controller 500 may select, as valid discrete time voltage data, discrete time voltage data for which the discrete time current data or the discrete time current variation data of the discrete time current data falls within a reference range (including 0). For example, the reference range may be a range in which the absolute value of the current data is 2 A or less and may correspond to the current variation range when the battery BAT is in a constant current mode.

For example, in operation S120 of generating diagnostic information, the remote controller 500 may determine a time range (e.g., a battery idle period) for the battery BAT based on at least one of the discrete time current data or the discrete time temperature data and select the discrete time voltage data within the determined time range as the valid discrete time voltage data. For example, the remote controller 500 may determine a time period during which the absolute value of the current data of the battery BAT is low and the temperature data is low as an idle period of the battery BAT.

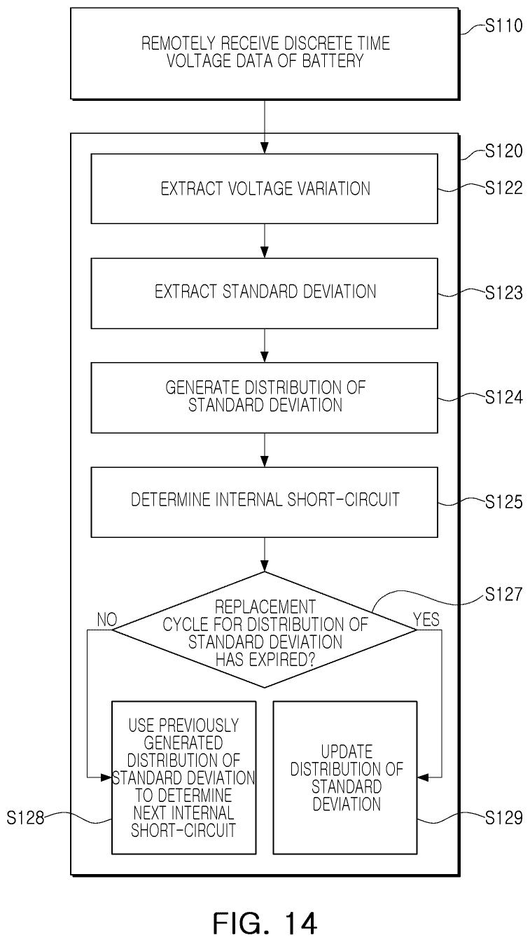

Referring to FIGS. 4 and 14, depending on the design, in operation S120 of generating diagnostic information, the remote controller 500 may check whether a replacement cycle for the distribution of standard deviation data has expired (S127), and if the replacement cycle has not expired, the remote controller may use the previously generated distribution of standard deviation data for the next internal short-circuit determination (S128), and if the replacement cycle has expired, the remote controller may update the distribution of standard deviation data (S129).

For example, since the variables (e.g., SOC, SOH, current, temperature) other than the self-discharge rate of the plurality of battery cells 11, 12, and 13 may be variables changing slowly over a long period of time, a slight difference in measurement time between the standard deviation data distributed in the distribution of standard deviation data may be acceptable. For example, using the previously generated distribution of standard deviation data for the next internal short-circuit determination may include increasing the values of data in the plurality of standard deviation sections D1, D2, D3, D4, D5, D6, and D7 by 1 each time based on the standard deviation data corresponding to the next internal short-circuit determination, rather than resetting the vertical axis value (Cell Count in FIG. 8) of the previously generated distribution of standard deviation data to 0. For example, the updating may be resetting the vertical axis value (Cell Count in FIG. 8) to 0.

Meanwhile, referring to FIG. 1, the remote controller 500 may be implemented as a computing system including at least one processor 501, a computer-readable storage medium 502, and a communication bus 503. The storage medium 502 may record one or more programs including instructions for executing a remote battery diagnostic method according to an embodiment of the present disclosure. The communication bus 503 may interconnect various other components of the remote controller 500, including the processor 501 and the computer-readable storage medium 502.

The processor 501 may cause the remote controller 500 to operate according to the embodiments described above. For example, the processor 501 may execute one or more programs stored on the computer-readable storage medium 502. The one or more programs may include one or more computer-executable instructions, which, when executed by the processor 501, may be configured to cause the remote controller 500 to perform operations according to the embodiments.

The computer-readable storage medium 502 may be configured to store computer-executable instructions or program code, program data, and/or other suitable forms of information. A program 502a stored on the computer-readable storage medium 502 includes a set of instructions executable by the processor 501. In an embodiment, the computer-readable storage medium 502 may be memory (volatile memory, such as random access memory, non-volatile memory, or a suitable combination thereof), one or more magnetic disk storage devices, optical disk storage devices, flash memory devices, or any other form of storage mediums accessible by the remote controller 500 and capable of storing desired information, or a suitable combination thereof.

The remote controller 500 may also include one or more input/output interfaces 505 providing interfaces for one or more input/output devices 504 and one or more network communication interfaces 506. The input/output interface 505 and the network communication interface 506 are connected to the communication bus 503. The network may be one of a cellular network, such as Global System for Mobile Communications (GSM), Enhanced Data Rates for GSM Evolution (EDGE), General Packet Radio Service (GPRS), Code Division Multiple Access (CDMA), Time Division-CDMA (TD-CDMA), Universal Mobile Telecommunications System (UMTS), Long Term Evolution (LTE), 5G, Wi-Fi, or another cellular network and may also be implemented using Ethernet, Media Oriented Systems Transport (MOST), Flexray, Controller Area Network (CAN), Local Interconnect Network (LIN), Internet, Bluetooth, Near Field Communication (NFC), Zigbee, or Radio Frequency (RF).

The input/output device 504 may be connected to other components of the remote controller 500 via the input/output interface 505. Exemplary input/output devices 504 may include input devices, such as a pointing device (e.g., a mouse or trackpad), a keyboard, a touch input device (e.g., a touchpad or touchscreen), a voice or audio input device, various types of sensor devices, and/or an imaging device, and/or output devices, such as a display device, a printer, a speaker, and/or a network card. The exemplary input/output device 504 may be incorporated into the remote controller 500 as a component constituting the remote controller 500 or may be connected to the remote controller 500 as a separate device distinct from the remote controller 500.

Meanwhile, the embodiments of the present disclosure may include a program for performing the methods described in this specification on a computer and a computer-readable recording medium including the program. The computer-readable recording medium may include program instructions, local data files, local data structures, etc., alone or in combination. The medium may be those specifically designed and configured for the present disclosure or may be those commonly available in the computer software field. Examples of computer-readable recording medium include magnetic medium, such as hard disks, floppy disks, and magnetic tapes, optical recording medium, such as CD-ROMs, DVDs, and hardware devices specifically configured to store and perform program instructions, such as ROM, RAM, flash memory, etc. Examples of the program may include not only machine language code, such as that generated by a compiler, but also high-level language code that may be executed by a computer using an interpreter or the like.

The remote battery diagnostic apparatus, method, and storage medium according to an embodiment of the present disclosure may be advantageous in satisfying the overall data throughput required for diagnosis and may improve battery diagnosis performance (e.g., accuracy, reliability, and speed).

Those skilled in the art will appreciate that the present disclosure may be implemented in other specific forms without changing a technical spirit or essential characteristics. Therefore, the embodiments described above should be understood as illustrative in all respects and not restrictive. The scope of the present disclosure is defined by the claims below rather than the detailed description above, and all changes or modifications derived from the meaning and scope of the claims and their equivalents should be construed as being included within the scope of the present disclosure.

What is claimed is:

1. A remote battery diagnostic apparatus comprising:
a remote controller remotely disposed from a device in which a battery including a plurality of battery cells is disposed and remotely receiving discrete time voltage data of each of the plurality of battery cells from a battery management controller of the battery,
wherein the remote controller detects a battery cell outside a normal range of fluctuation index distribution data in which the plurality of battery cells are distributed according to a voltage fluctuation index of the discrete time voltage data and generates diagnostic information for the battery.

2. The remote battery diagnostic apparatus of claim 1, wherein the remote controller generates discrete time voltage variation data of the discrete time voltage data and generates standard deviation data of the discrete time voltage variation data as the voltage fluctuation index.

3. The remote battery diagnostic apparatus of claim 2, wherein an adjacent time interval of the discrete time voltage data is 1 minute or less, and the discrete time voltage variation data corresponds to a differential value of the discrete time voltage data.

4. The remote battery diagnostic apparatus of claim 2, wherein the remote controller generates, as the fluctuation index distribution data, distribution of standard deviation data in which standard deviation data of each of the plurality of battery cells is distributed, and determines, as the normal range, a Gaussian distribution range of the standard deviation data of each of the plurality of battery cells.

5. The remote battery diagnostic apparatus of claim 1, wherein the remote controller remotely receives discrete time current data of the battery from the battery management controller, selects valid discrete time voltage data among the discrete time voltage data based on the discrete time current data, detects a battery cell outside the normal range of the fluctuation index distribution data in which the plurality of battery cells are distributed according to the voltage fluctuation index of the valid discrete time voltage data, and generates diagnostic information for the battery.

6. The remote battery diagnostic apparatus of claim 5, wherein the remote controller selects, as the valid discrete time voltage data, the discrete time voltage data, in which the discrete time current data or discrete time current variation data of the discrete time current data falls within a reference range.

7. The remote battery diagnostic apparatus of claim 1, wherein the remote controller remotely receives at least one of discrete time current data or discrete time temperature data of the battery from the battery management controller, determines an idle period of the battery based on at least one of the discrete time current data or the discrete time temperature data, detects a battery cell outside a normal range in the fluctuation index distribution data in which the plurality of battery cells are distributed according to the voltage fluctuation index of the discrete time voltage data corresponding to the idle period, and generates diagnostic information for the battery.

8. The remote battery diagnostic apparatus of claim 1, wherein the remote controller detects a battery cell discontinuously distributed among the plurality of battery cells distributed in the fluctuation index distribution data, as the battery cell outside the normal range.

9. The remote battery diagnostic apparatus of claim 1, wherein the remote controller determines a battery cell with a voltage change greater than an upper limit of the normal range in the fluctuation index distribution data to be an internal short-circuit battery cell and generates diagnostic information for the battery.

10. The remote battery diagnostic apparatus of claim 1, wherein the remote controller remotely transmits diagnostic information for the battery to the battery management controller.

11. The remote battery diagnostic apparatus of claim 1, wherein the remote controller remotely receives discrete time voltage data of a plurality of battery cells from a plurality of battery management controllers respectively corresponding to the plurality of batteries, each including a plurality of battery cells, and generates diagnostic information for each of the plurality of batteries.

12. The remote battery diagnostic apparatus of claim 1, wherein the device in which the battery is disposed includes a vehicle,
the battery and the battery management controller are disposed in the vehicle, and
the remote controller is disposed remotely from the vehicle.

13. A remote battery diagnostic method comprising:
remotely disposed from a device in which a battery including a plurality of battery cells is disposed and remotely receiving discrete time voltage data of each of the plurality of battery cells from a battery management controller of the battery, and
generating diagnostic information for the battery by detecting a battery cell outside a normal range of fluctuation index distribution data in which the plurality of battery cells are distributed according to a voltage fluctuation index of the discrete time voltage data.

14. The remote battery diagnostic method of claim 13, wherein
the generating of the diagnostic information includes:
extracting discrete time voltage variation data of the discrete time voltage data; and
extracting, as the voltage fluctuation index, standard deviation data of the discrete time voltage variation data.

15. The remote battery diagnostic method of claim 14, wherein
the generating of the diagnostic information further includes:
generating, as the fluctuation index distribution data, distribution of standard deviation data in which standard deviation data of each of the plurality of battery cells is distributed; and
generating diagnostic information for the battery by determining a battery cell having a voltage change greater than an upper limit of the normal range in the fluctuation index distribution data to be an internal short-circuit battery cell.

16. The remote battery diagnostic method of claim 15, wherein the generating of the diagnostic information further includes remotely transmitting the diagnostic information for the battery to the battery management controller.

17. The remote battery diagnostic method of claim 15, wherein the generating of the diagnostic information includes checking whether a replacement cycle of the distribution of standard deviation data has expired, using previously generated distribution of standard deviation data to determine a next internal short-circuit when the replacement cycle has not expired, and updating the distribution of standard deviation data when the replacement cycle has expired.

18. The remote battery diagnostic method of claim 13, wherein
the remotely receiving includes remotely receiving at least one of discrete time current data or discrete time temperature data of the battery from the battery management controller, and
the generating of the diagnostic information includes selecting discrete time voltage data belonging to a time range determined based on at least one of the discrete time current data or the discrete time temperature data and generating diagnostic information for the battery by detecting a battery cell outside the normal range of the fluctuation index distribution data in which the plurality of battery cells are distributed according to a voltage fluctuation index of the selected discrete time voltage data.

19. The remote battery diagnostic method of claim 13, wherein
the remotely receiving includes remotely receiving discrete time voltage data of the plurality of battery cells from a plurality of battery management controllers respectively corresponding to a plurality of batteries, each including a plurality of battery cells,
the device in which the battery is disposed includes a vehicle,
the vehicle is a plurality of vehicles,
the plurality of batteries and the plurality of battery management controllers are disposed in the plurality of vehicles, and
the generating of the diagnostic information includes generating diagnostic information for each of the plurality of batteries.

20. A storage medium recorded thereon one or more programs including instructions for executing the remote battery diagnosis method of claim 13.
